(19) United States
(12) Patent Application Publication
(10) Pub. No.: US 2022/0319838 A1
(43) Pub. Date: Oct. 6, 2022

(54) Method of Line Roughness Reduction and Self-Aligned Multi-Patterning Formation Using Tone Inversion

(71) Applicant: Tokyo Electron Limited, Tokyo (JP)

(72) Inventors: Eric Chih-Fang Liu, Albany, NY (US); Angelique Raley, Albany, NY (US); Kai-Hung Yu, Albany, NY (US)

(21) Appl. No.: 17/220,025

(22) Filed: Apr. 1, 2021

(51) Int. Cl. H01L 21/027; G03F 7/09; H01L 21/311

(52) U.S. Cl. CPC H01L 21/0274; G03F 7/094; G03F 7/091; H01L 21/31144

(57) ABSTRACT

A substrate is provided with a patterned layer, such as, a photo resist layer which may exhibit line roughness. The patterned layer may be an EUV photo resist layer utilized in a self-aligned multi-patterning process. A tone inversion process having a tone inversion layer is utilized along with a surface treatment of a sidewall of the tone inversion layer so as to improve line roughness characteristics of the process. More specifically, a tone inversion layer may be patterned and then sidewalls of the tone inversion layer may be treated. A fill material may then be deposited upon the substrate including adjacent the sidewalls of the tone inversion layer. When the tone inversion layer is removed, the roughness of the fill material will be reduced due to the use of the sidewall treatment.

### BACKGROUND

The present disclosure relates to the processing of substrates, such as for example, semiconductor substrates. In particular, it provides a novel method to pattern substrates having very narrow pitch designs.

As geometries in substrate processing continue to shrink, the technical challenges to forming structures on substrates via photolithography techniques increase. As requirements for lower pitch structures arose, a variety of photolithography techniques have been utilized for achieving suitable photolithography for such narrow pitches including extreme ultraviolet (EUV) lithography (lithography utilizing wavelengths of light in the EUV range, most typically 13.5 nm wavelengths), multiple patterning schemes (such as self-aligned double patterning (SADP), self-aligned triple patterning (SATP), etc.), argon fluoride (ArF) lithography, or other narrow pitch patterning methods.

It has been found that as pitches and dimensions decrease, the roughness of patterned lines increases. For example, line edge roughness (LER) performance degrades during the pattern transfer process. LER represents the departure of the edge of a line from a desired edge pattern (typically straight). Thus, the LER represents the amount of deviation from the desired edge (from a top view) and typically is represented in units of nanometers. Another measure of roughness is line width roughness (LWR). LWR represents the amount of deviation from the desired width of a line (from a top view) and is typically represented in units of nanometers. Another measure of roughness is sidewall width roughness (SWR). SWR represents the amount of deviation from the desired sidewall (typically a straight line) as viewed from a cross section view. As the feature size is reduced, the roughness (LER, LWR and SWR) has become recognized as a critical concern. The effects of roughness have become particularly problematic for EUV lithography where the photo resist height may be short and the patterned photo resist exhibits a high degree of roughness.

Conventional EUV lithography techniques attempt to address the incoming photo resist roughness by use of a plasma treatment before transferring the photo resist pattern to an underlying layer. More specifically, a patterned photo resist layer (for example a patterned EUV photo resist layer) may be formed over a plurality of underlying layers, including but not limited to antireflective layers, planarization layers, hard mask layers, target etch layers (to which the pattern of the patterned photo resist layer is to be transferred), etc. The patterned EUV photo resist layer may exhibit an unsatisfactory amount of line roughness as is known in the art. A plasma treatment may be applied to the patterned EUV photo resist layer to smooth the roughness before patterned EUV photo resist layer is used as a mask for etching one or more of the underlying layers. However, though such plasma treatment may decrease roughness, the height of the photo resist will generally be decreased. Then, during the pattern transfer to the underlying layers, the transfer process may break through the photo resist due to the decreased photo resist height and the selectivity of the process. The patterned EUV photo resist layer may even be completely removed during the pattern transfer, impacting the patterned formation in the layers underlying the photo resist. In this manner, roughness may be improved. However, the lithographic height of the photo resist may decrease and result in resist and pattern breaks caused by mask breakdown and/or critical dimension (CD) loading from mask selectivity. A trade off, therefore, exists between roughness improvement and the desired photo resist height and patterning. This trade off may be particularly problematic with regard to the use of EUV photo resists for the narrow dimensions in self-aligned multi-patterning processes (such as self-aligned double patterning (SADP), self-aligned triple patterning (SATP), etc.).

FIGS. 1A-1D illustrate one exemplary SADP process flow which may be susceptible to EUV patterning line roughness problems. As shown in FIG. 1A, a substrate 100 may be comprised of underlying layers 105 (for example various patterned and unpatterned layers formed during substrate processing). A floor layer 110 and a target etch layer 115. Target etch layer 115 is the layer within which the mandrels utilized in the SADP process flow will eventually be formed. An antireflective layer 120, for example, a silicon antireflective coating (SiARC) may also be provided. Finally, a patterned photo resist layer 125 is provided as shown. In an exemplary embodiment, the photo resist layer 125 may be formed of an EUV photo resist. The patterned photo resist layer 125 may be subjected to techniques described above for dealing with line roughness, resulting in the process tradeoffs mentioned. The antireflective layer 120 and the target etch layer 115 may be etched to form the mandrels as shown in FIG. 1B. A spacer deposition layer 130 may be formed over the substrate as shown in FIG. 1C. Then, as well known in the art, the substrate may be subjected to a spacer etch and mandrel pull process to leave spacers 135 which form the desired pattern of the SADP process flow. It will be recognized that the SADP process described above and the materials utilized for the various layers is merely exemplary of one process flow that and wide range of other process flows may have undesirable line roughness characteristics.

To improve the reliability and performance of EUV lithography and self-aligned multi-patterning processes, it would be desirable to provide an improved process for reducing line roughness issues.

### SUMMARY

Described herein is an innovative method to perform photo lithography pattern transfer. A substrate is provided with a patterned layer, such as for example, a photo resist layer, which may exhibit line roughness. In one exemplary embodiment, the patterned layer may be an EUV photo resist layer utilized in a self-aligned multi-patterning process. A tone inversion process having a tone inversion layer is utilized along with a surface treatment of a sidewall of the tone inversion layer so as to improve line roughness characteristics. More specifically, a tone inversion layer may be patterned and then sidewalls of the tone inversion layer may be treated. A fill material may then be deposited upon the substrate including adjacent the sidewalls of the tone inversion layer. When the tone inversion layer is removed, the roughness of the fill material will be reduced due to the use of the sidewall treatment.

In one embodiment, a first method for processing a substrate is disclosed. The first method comprises providing the substrate with a patterned photo resist layer, and providing a tone inversion layer underlying the patterned photo resist layer. The first method further comprises etching a pattern of the patterned photo resist layer in the tone inversion layer to form first lines and first spaces in the tone inversion layer, the first lines of the tone inversion layer have a first roughness. The first method further comprises treating a sidewall surface of the tone inversion layer and forming a fill material within the first spaces of the tone inversion layer. The first method additionally comprises removing the tone inversion layer, wherein after removing the tone inversion layer, the fill material forms second lines and second spaces, the second lines and the second spaces being tone inverted from the first lines and the first spaces, the second lines of the fill material having a second roughness. In the first method, the second roughness is less than the first roughness due to the treating of the sidewall surface of the tone inversion layer.

In one alternative of the first method, the treating the sidewall surface of the tone inversion layer comprises exposing the sidewall surface of the tone inversion layer to a plasma so that an interface between the tone inversion layer and the fill material becomes more hydrophobic. Further, treating the sidewall surface of the tone inversion layer may comprise depositing an inhibitor on the sidewall surface of the tone inversion layer so that an interface between the tone inversion layer and the fill material becomes more hydrophobic. Another alternative of the first method, the treating the sidewall surface of the tone inversion layer comprises smoothing the first roughness. In another alternative of the first method, the fill material is utilized to generate mandrels in a multi-patterning process, the mandrels formed in a target etch layer underlying the fill material. In still another alternative, the fill material is utilized to generate mandrels in a multi-patterning process, the mandrels formed in the fill material. In another alternative of the first method, the first roughness is at least one of line edge roughness, line width roughness or sidewall width roughness. In still another alternative, the tone inversion layer is a spin-on carbon layer and the fill material is a spin-on glass.

In another embodiment, a second method for processing a substrate is disclosed. The second method comprises providing the substrate with a patterned photo resist layer and providing a tone inversion layer underlying the patterned photo resist layer. The second method further comprises etching a pattern of the patterned photo resist layer in the tone inversion layer to form first lines and first spaces in the tone inversion layer, the first lines of the tone inversion layer have a first roughness. The second method further comprises treating a sidewall surface of the tone inversion layer and forming a fill material within the first spaces of the tone inversion layer, wherein the treating the sidewall surface of the tone inversion layer creates a change in a surface wettability of an interface between the tone inversion layer and the fill material. The second method also comprises removing the tone inversion layer, wherein after removing the tone inversion layer, the fill material forms second lines and second spaces, the second lines and the second spaces being tone inverted from the first lines and the first spaces, the second lines of the fill material having a second roughness. In the second method, the second roughness is less than the first roughness due to the change in the surface wettability caused by the treating of the sidewall surface of the tone inversion layer.

In one alternative of the second method, treating the sidewall surface of the tone inversion layer comprises exposing the sidewall surface of the tone inversion layer to a plasma so that the interface between the tone inversion layer and the fill material becomes more hydrophobic. In one embodiment, the plasma is a fluorocarbon based plasma. In another embodiment the tone inversion layer is a spin-on carbon layer. In another alternative of the second method, treating the sidewall surface of the tone inversion layer comprises depositing an inhibitor on the sidewall surface of the tone inversion layer so that the interface between the tone inversion layer and the fill material becomes more hydrophobic. In one embodiment, the inhibitor is formed using dimethyltrimethylsilylamine (TMSDMA). In another embodiment, the fill material is a spin-on glass. In yet another embodiment of the second method, the fill material is utilized to generate mandrels in a multi-patterning process, the mandrels formed in a target etch layer underlying the fill material. In one embodiment, the tone inversion layer is a spin-on carbon layer and the fill material is a spin-on glass. In still another embodiment of the second method, the fill material is utilized to generate mandrels in a multi-patterning process, the mandrels formed in the fill material.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIGS. 1A-1D (PRIOR ART) illustrate a prior art process of forming mandrels for using in a multiple patterning process flow.

FIGS. 2A-2H illustrate an exemplary process flow using the techniques described herein for line roughness improvement.

FIG. 3A illustrates the hydrophilic filling capability at the interface of a tone inversion layer without use of the sidewall treatment techniques disclosed herein.

FIGS. 3B-3C illustrate a cross-sectional view showing the hydrophobic effect at a tone inversion layer sidewall interface when using the sidewall treatment techniques disclosed herein.

FIGS. 3D-3E illustrate a top view showing the hydrophobic effect at a tone inversion layer sidewall interface when using the sidewall treatment techniques disclosed herein.

FIGS. 4 and 5 are flow charts of exemplary methods utilizing roughness improvement techniques disclosed herein.

### DETAILED DESCRIPTION

Described herein is an innovative method to perform photo lithography pattern transfer. A substrate is provided with a patterned layer, such as for example, a photo resist layer, which may exhibit line roughness. In one exemplary embodiment, the patterned layer may be an EUV photo resist layer utilized in a self-aligned multi-patterning process. A tone inversion process having a tone inversion layer is utilized along with a surface treatment of a sidewall of the tone inversion layer so as to improve line roughness characteristics. More specifically, a tone inversion layer may be patterned and then sidewalls of the tone inversion layer may be treated. A fill material may then be deposited upon the substrate including adjacent the sidewalls of the tone inversion layer. When the tone inversion layer is removed, the roughness of the fill material will be reduced due to the use of the sidewall treatment.

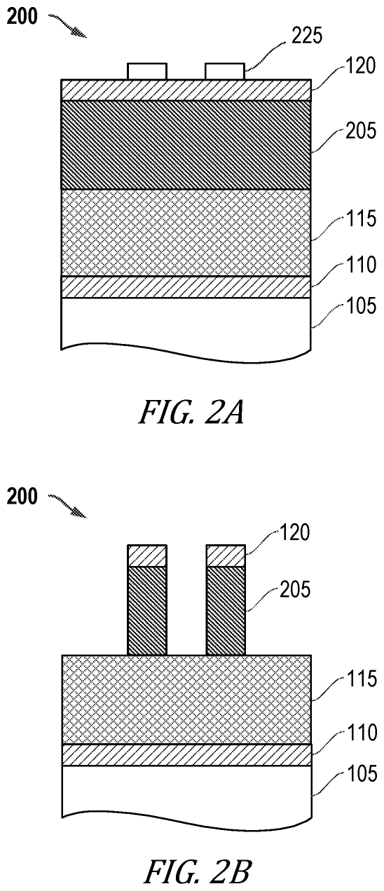

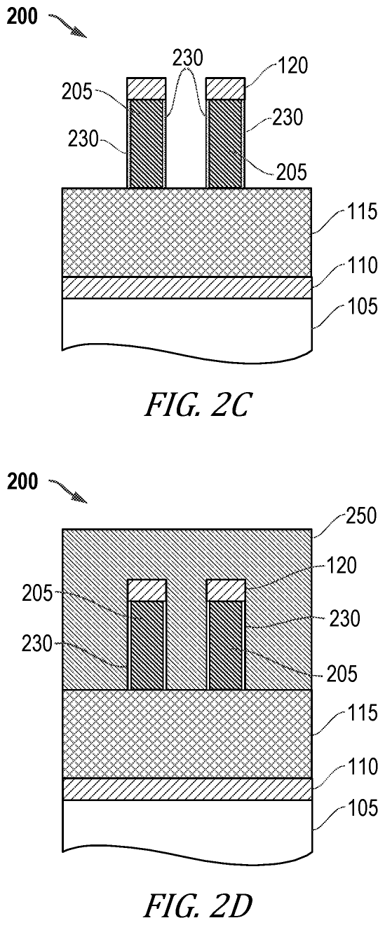

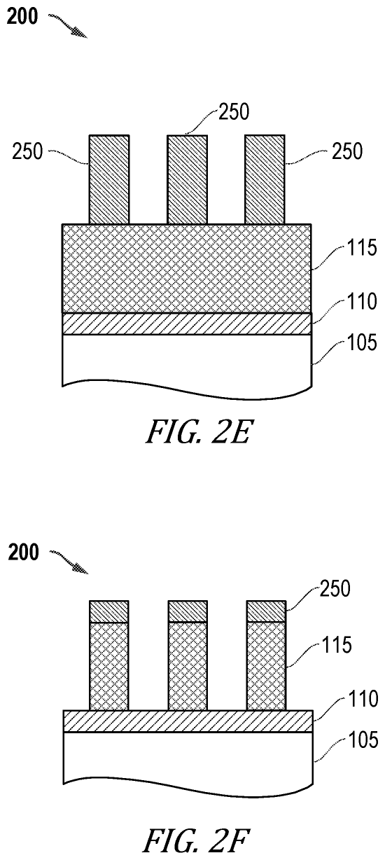

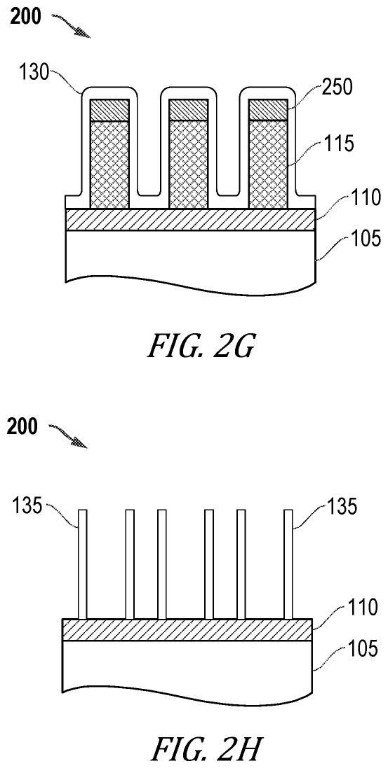

FIGS. 2A-2H illustrate one exemplary self-aligned multi-patterning process utilizing the tone inversion and surface treatment techniques described herein. It will be recognized that the process flow, layers, and materials shown and described with regard to these figures are merely exemplary. Thus, an exemplary embodiment of a method utilizing the techniques described herein may be seen with respect to the figures and description provided herein. In one embodiment, line roughness effects are lessened by use of a tone inversion layer and a surface treatment of the tone inversion layer. The process may improve the roughness characteristics of a patterned feature made from patterned EUV photo resist lines so as to provide more process margin during subsequent etching and pattern transfer.

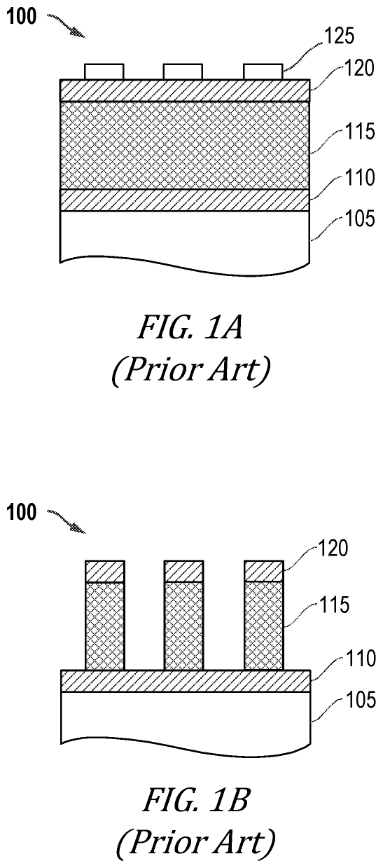

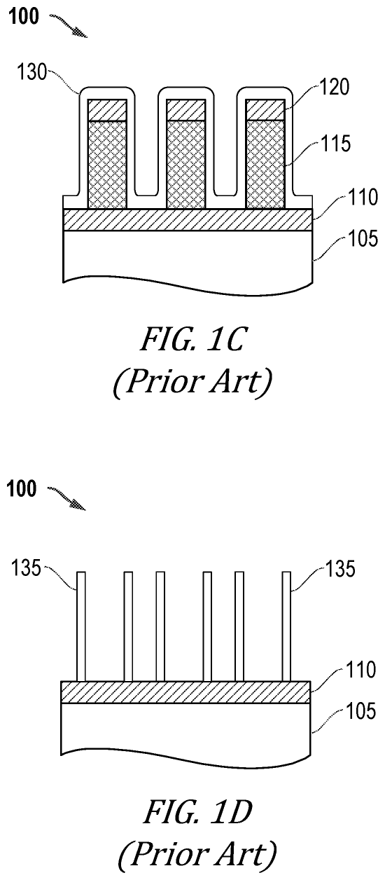

The tone inversion and surface treatment described herein may be used singularly or in combination, and may be used with other process flows to achieve improved line roughness characteristics. As shown in FIGS. 2A-2H, many of the layers and structures utilized] like reference numbers as the shown in FIGS. 1A-1D to illustrate layers, materials and structures that may be the same between the two sets of figures.

As compared to FIGS. 1A-1D, FIGS. 2A-2H utilized similar layers except for the inclusion of tone inversion layer 205, fill material 250, and the pattern of the photo resist layer is inverted between the two sets of figures. Thus, for example, the patterned photo resist layer 225 of FIG. 2A has a similar, but inverted, pattern as compared to the patterned photo resist layer 125 of FIG. 1A. In one exemplary embodiment, patterned photo resist layer 125 is formed on an EUV photo resist. As described in more detail below, tone inversion layer 205 will be utilized to form a pattern in fill material 250 that has an inverted pattern of the pattern photo resist layer 225. In one embodiment, tone inversion layer 205 is formed of a spin-on carbon (SOC) material. However, the use of spin-on carbon for tone inversion layer 205 is merely exemplary and other materials may be used including organic dielectric layer (ODL) materials, or amorphous carbon (a-C). In still other embodiments, other spin-on materials or even non spin-on materials may be utilized for the tone inversion layer, including but not limited to silicon dioxide, silicon nitride, silicon carbide, amorphous silicon, metallic oxide, metallic nitride, or other metallic materials.

The structure of the FIG. 2A may be provided on a substrate 200 utilizing any of a wide variety of substrate processing techniques to achieve the structure shown, including additional layers (not shown) underlying those layers shown. The substrates utilized with the techniques disclosed herein may be any substrates for which the patterning and etching of material is desirable. For example, in one embodiment, the substrate may be a semiconductor substrate having one or more semiconductor processing layers (all of which together may comprise the substrate) formed thereon. In one embodiment, the substrate may be a substrate that has been subject to multiple semiconductor processing steps which yield a wide variety of structures and layers, all of which are known in the substrate processing art. In one embodiment, the substrate may be a semiconductor wafer including the various structures and layers formed.

As shown in FIG. 2A, a patterned photo resist layer 225 is provided over various layers. As mentioned, the particular layers over which the patterned photo resist layer 225 is formed are merely exemplary and used to illustrate one exemplary process flow. As shown in FIG. 2A, the substrate 200 includes underlying layers 105, floor layer 110, target etch layer 115, tone inversion layer 205, antireflective layer 120 and patterned photo resist layer 225. The floor layer 110 may actually be comprised of multiple layers. For example, in one embodiment, the floor layer may be a stack of amorphous silicon, titanium nitride and oxide. It will be recognized, however, the particular floor layer will be dependent upon the particular process that is utilizing the techniques described herein. A target etch layer 115 may be in one embodiment a silicon nitride layer. However, other materials, including but not limited to, oxide, nitride, carbon, amorphous silicon, or metallic materials, may be utilized. The antireflective layer may be, in one example, a silicon antireflective layer.

Next, the process flow proceeds to etch the antireflective layer 120 and the tone inversion layer 205 according to the pattern of the patterned photo resist layer 225 to provide the structures as shown in FIG. 2B. As known in the art, the etching process may be a plasma etch process though other etching processes may be utilized and the techniques described herein are not limited to a particular etch. In one embodiment, a CHₓF_{y} based plasma may be used to etch the antireflective layer 120 (in this case a silicon antireflective layer) and an oxygen (O₂) based plasma may be used to etch the SOC tone inversion layer 205. The structure of FIG. 2B may then be subjected to a sidewall surface treatment process. More specifically, the exposed sidewalls of the tone inversion layer 205 may be subjected to a surface treatment. The treating of the sidewalls can be performed in different manners. The surface treatment may in one embodiment be obtained by exposing the sidewall to a plasma. As discussed in more detail below, the plasma may change the surface of the tone inversion layer 205. In another embodiment, the surface treatment may comprise the deposition of a monolayer (less than 5 nm and more preferably 1 to 2 nm) of an inhibitor on the sidewall. Further, in another embodiment (as discussed below) the treating of the sidewalls may perform a smoothing process on the sidewalls. Thus, treated sidewalls 230 of the tone inversion layer 205 are provided as shown in FIG. 2C. As will be discussed in more detail below, the surface treatment of the tone inversion layer 205 will provide improved line roughness characteristics of a material that is formed adjacent to the treated sidewalls 230 of the tone inversion layer 205. Next a fill material 250 may be deposited on the substrate as shown in FIG. 2D. The fill material 250 may be, in one embodiment, a spin-on material. In one exemplary embodiment, a spin-on glass is used for fill material 250. In one exemplary embodiment, the SOG is a low cure temperature SOG as high curing temperatures may interact with the SOC layer. Eventually, as discussed below, the fill material will have a pattern that corresponds to a mandrel pattern so that the fill material 250 may be used as a mask to etch mandrels in the target etch layer 115. The fill material 250 may be formed of a wide variety of materials, including but not limited to, other spin-on materials such silicon-based oxide, nitride, carbide, oxynitride, metallic-base oxide, or metallic-base nitride. Further, even non spin-on materials may be utilized, for example but not limited to, chemical vapor deposition (CVD) or atomic layer deposition (ALD) filled silicon-based oxide, nitride, carbide, oxynitride, metallic-base oxide, metallic-base nitride, amorphous silicon or metallic material. As discussed below, the sidewalls of the fill material 250 that are adjacent the treated sidewalls of the 230 of the tone inversion layer 205 will exhibit improved line roughness characteristics due to sidewall treatment of the tone inversion layer.

The process flow may continue by removing the upper portions of the fill material 250 to expose the remaining antireflective layer 120. The removal process may be performed by a plasma etch, planarization or other removal techniques. The remaining antireflective layer 120 and the underlying tone inversion layer 205 may then be removed (or “pulled”), for example with a plasma etch, wet etch or combination of etches. The resulting pattern on the substrate 200 is shown in FIG. 2E. When comparing FIG. 2B and FIG. 2E, it will be noted that the lines and spaces of the patterns of the two figures are tone inverted. More specifically, the lines and spaces of the mask material 250 layer are tone inverted from the lines and spaces of the tone inversion layer 205.

Then, the fill material 250 may be used as mask during an etch of the target etch layer 115 to form mandrels. Again, such etch may be a plasma etch, though the etch of the target etch layer 115 is not limited to any particular plasma etch or even plasma etching at all. FIG. 2F illustrates the substrate 200 after the etch of the target etch layer 115. As shown, a smaller amount of fill material 250 may remain after etching the target etch layer 115. Alternatively, the remaining fill material 250 may be completely removed through additional processing. Because of the improved line roughness characteristics of the fill material 250, the mandrels formed in the target etch layer 115 will similarly have improved line roughness characteristics. In this manner, the use of a sidewall surface treatment process in the tone inversion layer followed by the deposition of a fill material provides improved line roughness characteristics to mandrels. It will be noted that due to the use of the tone inversion layer 205 and fill material 250, the mandrels formed in target etch layer 115 are tone inverted from the original patterned photo resist layer 225.

Similar to FIG. 1C, a spacer deposition layer 130 may be formed over the substrate as shown in FIG. 2G. The spacer deposition layer 130 may be formed of any of a wide variety of materials, including but not limited to oxides, carbide, oxynitride, metallic-base oxide, metallic-base nitride, amorphous silicon or metallic materials, etc. as is known in the art. Then, as well known in the art, the substrate may be subjected to a spacer etch and mandrel pull process to leave spacers 135 as shown FIG. 2H. The spacers 135 form the desired pattern of the SADP process flow. As with the mandrels, these spacers will have improved line roughness characteristics which tie back to the improvements in the line roughness of the patterned fill material 250 discussed above. The spacers 135 may then be utilized as a mask to etch the underlying floor layer 110 as is known in the art (not shown in the figures). It will be recognized that the SADP process described above and the materials utilized for the various layers is merely exemplary of one process flow that and wide range of other process flows may utilize the tone inversion and sidewall treatment techniques discussed above.

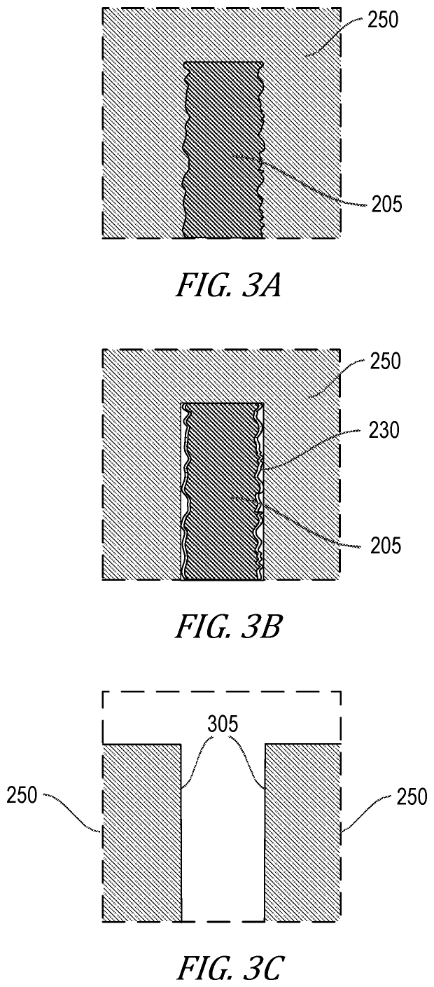

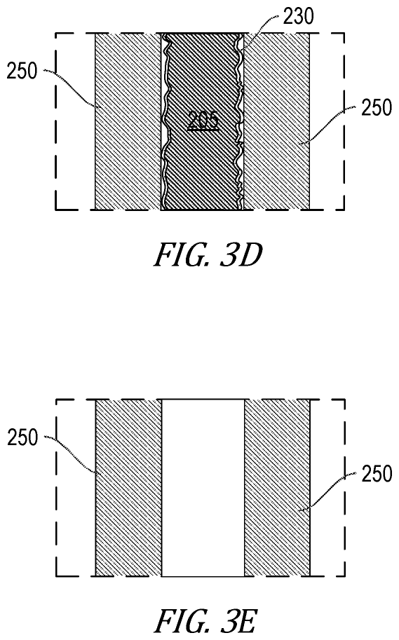

The impact of the sidewall treatment on the sidewalls of the tone inversion layer 205 is discussed in more detail with regard to FIG. 3A-FIG. 3E. In general, the process techniques described above provide a structure having a first roughness and though the use of the techniques disclosed yield second structure having a second roughness, the second roughness being less than the first roughness.

FIGS. 3A, 3B, and 3C illustrate the roughness in a cross-sectional view of the roughness effects (in this case SWR) and FIGS. 3D and 3E illustrate the roughness in a top view of the roughness effects (LER and LWR). FIG. 3A illustrates a tone inversion layer 205 being directly covered with the fill material 250 (for example a spin-on deposition) without the use of a sidewall treatment. As shown in FIG. 3A, without the sidewall treatment, the fill material 250 generally conforms to the rough and irregular sidewalls of the tone inversion layer 205. For example, in the case of a tone inversion layer 205 formed of a spin-on carbon and fill material 250 formed of a spin-on glass, the surface hydrophobicity of the interface is generally hydrophilic such that the spin-on glass will fill and conform to the roughness irregularities of the tone inversion layer 205. The surface treatment that is utilized to treat the surface of tone inversion layer 205 to form the treated sidewalls 230 as described above, changes the surface hydrophobicity. Specifically, the surface treatment results in a hydrophobic interface relationship. Thus, the filling capacity of the spin-on glass fill material 250 is changed. More specifically, because the relationship is now hydrophobic, the fill material 250 will not fill and conform to rough areas of the sidewalls of the tone inversion layer 205. This result is shown in FIG. 3B. Then, when the tone inversion layer 205 is removed, the sidewalls 305 of the fill material 250 have a decrease in line roughness as shown in FIG. 3C. It is noted that as shown in the figures the line roughness is illustrated in an X-plane cross-sections of a line, but similar effects will occur in a top view of a line such as shown in FIGS. 3D and 3E. In this manner, line edge roughness (LER), line width roughness (LWR) and sidewall roughness (SWR) may all be improved.

A variety of surface treatments may be utilized to treat the sidewalls of the spin-on carbon (SOC) tone inversion layer. Further, different treatments may result in differing surface wettability as reflected by the wet contact angle (WCA) of the spin-on glass mask (SOG) fill material. For example, without a surface treatment a WCA of 22 degrees may be observed. After using a carbon fluoride CFₓ plasma treatment, a WCA of 63 degrees may be observed. Further after depositing an inhibiter on the sidewalls as a surface treatment, a WCA of 95 degrees may be observed. It will be recognized that as the WCA increases, the filling of the rough sidewalls of the SOC tone inversion layer will decrease and correspondingly the line roughness will decrease. In one example line edge roughness (LER) may drop from an untreated sidewall process having an LER of 2.1 nm, to an LER of 1.83 nm for a plasma treated sidewall, and to an LER of 1.74 nm for a sidewall subjected to an inhibitor deposition.

As mentioned, a variety of surface treatment process options exist. The concepts described herein are, thus, not limited to a specific sidewall surface treatment as the advantages described herein may be obtained from various treatments. One exemplary treatment is performed by exposing the sidewalls to a plasma which changes the wettability properties of the tone inversion layer 205 sidewalls. For an SOC tone inversion layer, one such plasma is a fluorocarbon based plasma. The plasma may be generated with the use of fluorocarbon gasses and may further include other gases. The fluorocarbon gases may include, for example, a variety of CₓF_{y} gases. The fluorocarbon based plasma may be in some embodiments utilize a CF₄, C₄F₈, and/or C₄F₆ chemistry. Other fluorine based plasma chemistries such as CHₓF_{y} may also be utilized. The chemistries describe polymerize the sidewall surfaces, for example forming a CF polymer. The deposited polymer films generate a non-polarized function group on the surface which inhibits the adhesion/attachment of liquid/gas onto the surface and changes the wettability. In one embodiment, the plasma sidewall treatment may be performed in-situ in the etch tool utilized to etch the tone inversion layer, right after the tone inversion layer is etched.

As mentioned above, other sidewall treatments may relate to a deposition process used for forming an inhibitor monolayer on the sidewalls of the tone inversion layer to provide the desired wettability change (and corresponding WCA change). Thus, the inhibitor inhibits the filling and conformance of the fill material that is later deposited adjacent the tone inversion layer sidewalls. In one embodiment, the inhibitor is formed by using dimethyltrimethylsilylamine (TMSDMA) in a chemical vapor deposition process that provides a silylation reaction to form to a monolayer (sub nm) thickness of —O—Si(CH₃)₃. Other materials may also be used to form an inhibitor, such as but not limited to, hexametyldisilazane (HMDS), Dimetylsilanedimetylamine (DMSDMA), Trimethylsilyl-pyrrole (TMS-Pyrrole), Bisdimethylamindimethylsilane BDMADMS), TrimethylDiSilazane (TMDS), or other low k restoration (LKR) chemistries. Further, the inhibitor is not limited to those described and a wide range of materials that provide a desired wettability change may be utilized, depending upon the particular tone inversion layer material and fill material utilized. The inhibitor deposition process may be a chemical vapor deposition process, atomic layer deposition process, or other thin layer deposition process. The deposition of the inhibited (for example using a TMSDMA process) forms an inhibitor film which generates a non-polarized function group on the surface which inhibits the adhesion/attachment of liquid/gas onto the surface and change the wettability.

In yet another embodiment, the material may be deposited on the sidewalls of the tone inversion layer 205 to form the treated sidewalls 230 such that the sidewalls are directly smoothed by preferentially filling valleys in the rough areas so as to reduce the relative height of rough asperities of the surface. One such smoothing approach is disclosed in US Patent Application Publication No. 2021/0020448 to Lou, Raley and Ranjan, entitled “Method and Structure for Smoothing Substrate Patterns or Surfaces,” the disclosure of which is expressly incorporated by reference. In this approach, an atomic layer deposition process is utilized that smooths out line edge roughness of a pattern feature by preferentially filling valleys in the rough surface. Using such a technique, by smoothing the differences between peaks and valleys on the sidewalls of the tone inversion layer, the fill material that is deposited adjacent the sidewalls will likewise have smoother edges when the tone inversion layer is removed. The resulting structures formed using the fill material as a mask (for example the mandrels) will correspondingly have decreased line roughness.

As discussed above, the use of a tone inversion layer and sidewall surface treatment is described as implemented in a SADP process. However, it will be recognized that the techniques are not limited to an SADP process or even a multi-patterning process. Rather, a wide range of substrate processes may advantageously utilize the techniques described herein. Moreover, the techniques disclosed herein may be utilized at any stage of the substrate process flow, for example front end of line (FEOL) processing steps and/or back end of line (BEOL) processing steps. Further, though the process described above illustrates a process flow in which the fill material is utilized as a masking layer for etching mandrels in the target etch layer, it will be recognized that other techniques may be utilized. Thus, for example, the fill material itself may serve as the mandrels without the use of a target etch layer. In such a case, the spacer deposition may be performed directly upon the patterned masking material. Such variation will be dependent upon the particular process step, the materials being utilized for the various layers, and the layer for which the final etch pattern is desired to be transferred to.

In one exemplary 40 nm pitch process, significant roughness improvement may be seen. For example, with a line critical dimension (CD) of 17 nm, and a space CD of 23 nm, the roughness of the EUV photo resist after develop may be LER 2.31 nm, LWR 3.15 nm and SWR 3.16 nm. Using the SADP described to create a 20 nm pitch of 11 nm CD lines and 9 nm CD spaces, the spacer structures may exhibit roughness measurements of LER 1.71 nm, LWR 0.92 nm, and SWR 2.07 nm (improvements of 26%, 71% and 35% respectively).

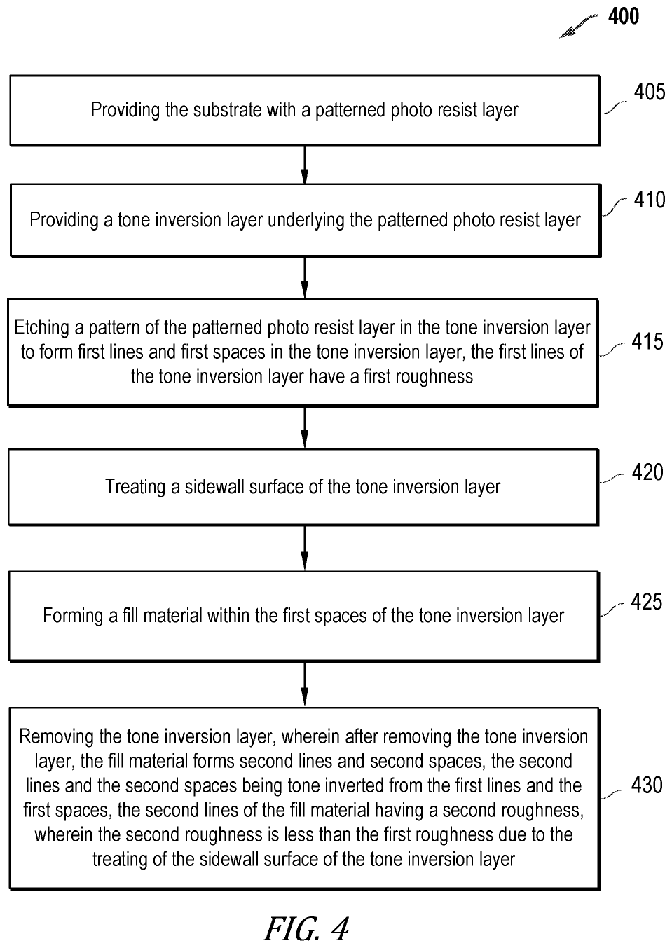

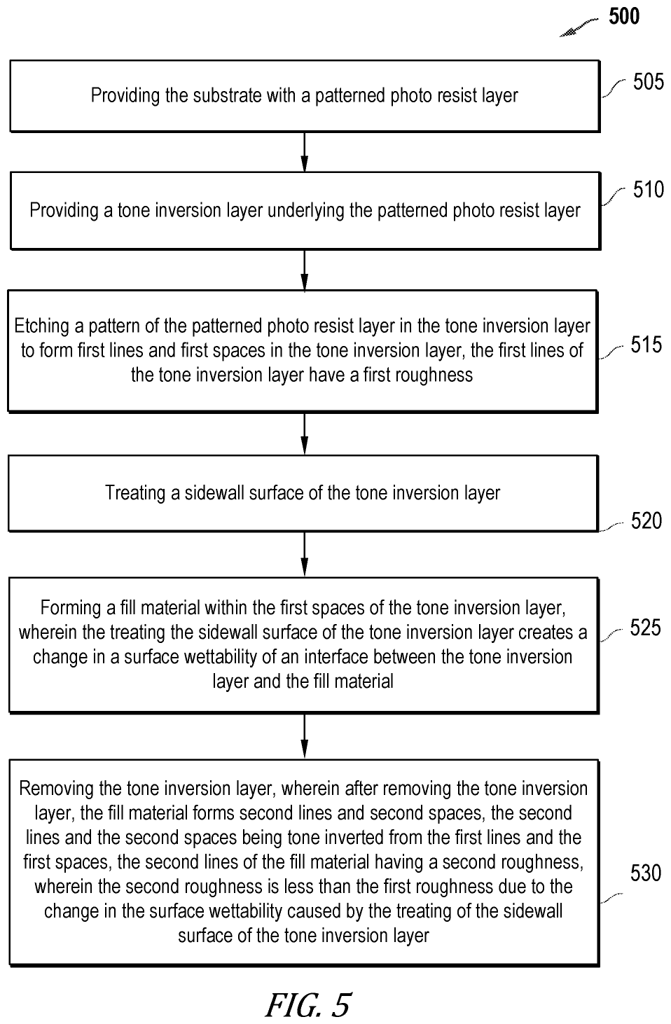

FIGS. 4-5 illustrate exemplary methods for use of the processing techniques described herein. It will be recognized that the embodiments of FIGS. 4-5 are merely exemplary and additional methods may utilize the techniques described herein. Further, additional processing steps may be added to the methods shown in FIGS. 4-5 as the steps described are not intended to be exclusive. Moreover, the order of the steps is not limited to the order shown in the FIGS. 4-5 as different orders may occur and/or various steps may be performed in combination or at the same time.

FIG. 4 illustrates a method for processing a substrate. As shown in FIG. 4, the method includes a step 405 of providing the substrate with a patterned photo resist layer. The method also includes step 410 of providing a tone inversion layer underlying the patterned photo resist layer. The method further includes step 415 of etching a pattern of the patterned photo resist layer in the tone inversion layer to form first lines and first spaces in the tone inversion layer, the first lines of the tone inversion layer have a first roughness. The method further includes step 420 of treating a sidewall surface of the tone inversion layer and step 425 of forming a fill material within the first spaces of the tone inversion layer. The method also includes step 430 of removing the tone inversion layer, wherein after removing the tone inversion layer, the fill material forms second lines and second spaces, the second lines and the second spaces being tone inverted from the first lines and the first spaces, the second lines of the fill material having a second roughness, wherein the second roughness is less than the first roughness due to the treating of the sidewall surface of the tone inversion layer.

FIG. 5 illustrates a method for processing a substrate. As shown in FIG. 5, the method includes a step 505 of providing the substrate with a patterned photo resist layer. The method also includes step 510 of providing a tone inversion layer underlying the patterned photo resist layer and step 515 of etching a pattern of the patterned photo resist layer in the tone inversion layer to form first lines and first spaces in the tone inversion layer, the first lines of the tone inversion layer have a first roughness. The method further includes step 520 of treating a sidewall surface of the tone inversion layer and step 525 of forming a fill material within the first spaces of the tone inversion layer, wherein the treating the sidewall surface of the tone inversion layer creates a change in a surface wettability of an interface between the tone inversion layer and the fill material. The method further includes step 530 of removing the tone inversion layer, wherein after removing the tone inversion layer, the fill material forms second lines and second spaces, the second lines and the second spaces being tone inverted from the first lines and the first spaces, the second lines of the fill material having a second roughness, wherein the second roughness is less than the first roughness due to the change in the surface wettability caused by the treating of the sidewall surface of the tone inversion layer.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

Systems and methods for processing a substrate are described in various embodiments. The substrate may include any material portion or structure of a device, particularly a semiconductor or other electronics device, and may, for example, be a base substrate structure, such as a semiconductor substrate or a layer on or overlying a base substrate structure such as a thin film. Thus, the term “substrate” is not intended to be limited to any particular base structure, underlying layer or overlying layer, patterned or unpatterned, but rather, is contemplated to include any such layer or base structure, and any combination of layers and/or base structures. In some cases, the term “substrate” may be used to describe a patterned or unpatterned wafer.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the inventions will be apparent to those skilled in the art in view of this description. Accordingly, this description is to be construed as illustrative only and is for the purpose of teaching those skilled in the art the manner of carrying out the inventions. It is to be understood that the forms and method of the inventions herein shown and described are to be taken as merely exemplary embodiments. Equivalent techniques may be substituted for those illustrated and described herein and certain features of the inventions may be utilized independently of the use of other features, all as would be apparent to one skilled in the art after having the benefit of this description of the inventions.

What is claimed is:

1. A method for processing a substrate, comprising:
providing the substrate with a patterned photo resist layer;
providing a tone inversion layer underlying the patterned photo resist layer;
etching a pattern of the patterned photo resist layer in the tone inversion layer to form first lines and first spaces in the tone inversion layer, the first lines of the tone inversion layer have a first roughness;
treating a sidewall surface of the tone inversion layer;
forming a fill material within the first spaces of the tone inversion layer; and
removing the tone inversion layer, wherein after removing the tone inversion layer, the fill material forms second lines and second spaces, the second lines and the second spaces being tone inverted from the first lines and the first spaces, the second lines of the fill material having a second roughness,
wherein the second roughness is less than the first roughness due to the treating of the sidewall surface of the tone inversion layer.

2. The method of claim 1, wherein treating the sidewall surface of the tone inversion layer comprises exposing the sidewall surface of the tone inversion layer to a plasma so that an interface between the tone inversion layer and the fill material becomes more hydrophobic.

3. The method of claim 1, wherein treating the sidewall surface of the tone inversion layer comprises depositing an inhibitor on the sidewall surface of the tone inversion layer so that an interface between the tone inversion layer and the fill material becomes more hydrophobic.

4. The method of claim 1, wherein treating the sidewall surface of the tone inversion layer comprises smoothing the first roughness.

5. The method of claim 1, wherein the fill material is utilized to generate mandrels in a multi-patterning process, the mandrels formed in a target etch layer underlying the fill material.

6. The method of claim 1, wherein the fill material is utilized to generate mandrels in a multi-patterning process, the mandrels formed in the fill material.

7. The method of claim 1, wherein the first roughness is at least one of line edge roughness, line width roughness or sidewall width roughness.

8. The method of claim 1, wherein the tone inversion layer is a spin-on carbon layer and the fill material is a spin-on glass.

9. A method for processing a substrate, comprising:
providing the substrate with a patterned photo resist layer;
providing a tone inversion layer underlying the patterned photo resist layer;
etching a pattern of the patterned photo resist layer in the tone inversion layer to form first lines and first spaces in the tone inversion layer, the first lines of the tone inversion layer have a first roughness;
treating a sidewall surface of the tone inversion layer;
forming a fill material within the first spaces of the tone inversion layer, wherein the treating the sidewall surface of the tone inversion layer creates a change in a surface wettability of an interface between the tone inversion layer and the fill material; and
removing the tone inversion layer, wherein after removing the tone inversion layer, the fill material forms second lines and second spaces, the second lines and the second spaces being tone inverted from the first lines and the first spaces, the second lines of the fill material having a second roughness,
wherein the second roughness is less than the first roughness due to the change in the surface wettability caused by the treating of the sidewall surface of the tone inversion layer.

10. The method of claim 9, wherein treating the sidewall surface of the tone inversion layer comprises exposing the sidewall surface of the tone inversion layer to a plasma so that the interface between the tone inversion layer and the fill material becomes more hydrophobic.

11. The method of claim 10, wherein the plasma is a fluorocarbon based plasma.

12. The method of claim 10, wherein the tone inversion layer is a spin-on carbon layer.

13. The method of claim 11, wherein the plasma is a fluorocarbon based plasma.

14. The method of claim 9, wherein treating the sidewall surface of the tone inversion layer comprises depositing an inhibitor on the sidewall surface of the tone inversion layer so that the interface between the tone inversion layer and the fill material becomes more hydrophobic.

15. The method of claim 14, wherein the inhibitor is formed using dimethyltrimethylsilylamine (TMSDMA).

16. The method of claim 15, wherein the fill material is a spin-on glass.

17. The method of claim 14, wherein the fill material is a spin-on glass.

18. The method of claim 9, wherein the fill material is utilized to generate mandrels in a multi-patterning process, the mandrels formed in a target etch layer underlying the fill material.

19. The method of claim 18, wherein the tone inversion layer is a spin-on carbon layer and the fill material is a spin-on glass.

20. The method of claim 9, wherein the fill material is utilized to generate mandrels in a multi-patterning process, the mandrels formed in the fill material.
